(19) United States
(12) Patent Application Publication
(10) Pub. No.: US 2026/0173633 A1
(43) Pub. Date: Jun. 18, 2026

(54) LIGHT EMITTING APPARATUS

(71) Applicant: SEOUL VIOSYS CO., LTD., Ansan-si (KR)

(72) Inventor: Seung Ryeol RYU, Ansan-si (KR)

(73) Assignee: SEOUL VIOSYS CO., LTD., Ansan-si (KR)

(21) Appl. No.: 19/418,635

(22) Filed: Dec. 12, 2025

Related U.S. Application Data
(60) Provisional application No. 63/734,722, filed on Dec. 16, 2024.

(51) Int. Cl. H10H 29/856; H10H 29/855

(52) U.S. Cl. CPC H10H 29/856; H10H 29/8552

(57) ABSTRACT

According to an aspect of the present disclosure, there may be provided a light emitting apparatus including: a light emitting device for generating light; a reflector disposed at a side of the light emitting device to reflect light toward the light emitting device; and a substrate for supporting the light emitting device and the reflector, wherein the reflector, when viewed from the side, has a region whose color differs from a color of the reflector when viewed from above.

### TECHNICAL FIELD

The present disclosure relates to a light emitting apparatus.

### BACKGROUND OF INVENTION

Recently, light emitting diodes (LEDs) have been widely used. A light emitting diode converts an electrical signal into a form of light, such as infrared, visible light, or ultraviolet light, using the characteristics of a compound semiconductor.

As the luminous efficiency of light emitting diodes has increased, light emitting devices are being applied in various fields including display devices, lighting equipment, and vehicle lamps.

### CONTENTS OF INVENTION

### Problems to be Solved by Invention

Embodiments provide a light emitting apparatus with improved contrast by minimizing optical interference between light emitting devices.

Furthermore, embodiments of the present disclosure provide a light emitting apparatus with improved light extraction efficiency.

### Means for Solving Problems

In accordance with an aspect of the present disclosure, there may be provided a light emitting apparatus including: a light emitting device for generating light; a reflector disposed at a side of the light emitting device to reflect light toward the light emitting device; and a substrate for supporting the light emitting device and the reflector, wherein the reflector, when viewed from the side, has a region whose color differs from a color of the reflector when viewed from above.

Further, there may be provided the light emitting apparatus in which the color of the reflector when viewed from above is black, and the color of the reflector when viewed from the side is white.

Further, there may be provided the light emitting apparatus in which a luminous intensity deviation of the light generated from the light emitting device is 0.015 or less, and the luminous intensity deviation is a luminous intensity deviation between light emitted upward among the light generated from the light emitting device and light emitted in a direction deviated from the upward direction among the light generated from the light emitting device.

Further, there may be provided the light emitting apparatus in which a luminance change rate of the light generated from the light emitting device is 50% or less, and the luminance change rate is a luminance change rate between light emitted upward among the light generated from the light emitting device and light emitted in a direction deviated from the upward direction among the light generated from the light emitting device.

Further, there may be provided the light emitting apparatus in which the reflector includes: a reflective region disposed at the side of the light emitting device to reflect light toward the light emitting device; and a light absorbing region covering the reflective region and absorbing light.

Further, there may be provided the light emitting apparatus in which a thickness of the reflective region is greater than a thickness of the light absorbing region.

Further, there may be provided the light emitting apparatus in which the reflective region and the light absorbing region are integrally formed, and an interface between the reflective region and the light absorbing region is non-uniform.

Further, there may be provided the light emitting apparatus in which the light emitting device includes: a first conductivity type semiconductor layer; an active layer stacked on the first conductivity type semiconductor layer; and a second conductivity type semiconductor layer stacked on the active layer, and wherein a width of the reflective region decreases as a distance upward from the active layer.

Further, there may be provided the light emitting apparatus in which at least a portion of the reflective region is disposed below any one of the first conductivity type semiconductor layer and the second conductivity type semiconductor layer.

Further, there may be provided the light emitting apparatus in which the reflective region and the light absorbing region include carbon, and a content of the carbon in the light absorbing region is higher than a content of the carbon in the reflective region.

Further, there may be provided the light emitting apparatus in which the reflective region and the light absorbing region are in contact with a side surface of the light emitting device, and an area of the side surface of the light emitting device that the reflective region contacts is greater than an area of the side surface of the light emitting device that the light absorbing region contacts.

Further, there may be provided the light emitting apparatus further including a molding layer stacked on the light emitting device and the light absorbing region, and a reflectance of the reflective region is greater than a reflectance of the molding layer.

Further, there may be provided the light emitting apparatus in which the reflective region includes a filler.

Further, there may be provided a light emitting apparatus including: a light emitting device for generating light; a substrate for supporting the light emitting device; a reflector located at a side of the light emitting device to reflect light toward the light emitting device; and an auxiliary layer stacked on the light emitting device and diffusing light, wherein a color of the reflector when viewed from above and a color of the reflector when viewed from a side are different.

Further, there may be provided the light emitting apparatus in which the reflector includes: a reflective region disposed at the side of the light emitting device to reflect light toward the light emitting device; and a light absorbing region stacked on the reflective region to cover the reflective region and absorbing light.

Further, there may be provided the light emitting apparatus further including a molding layer covering the reflector and the auxiliary layer, wherein refractive indices of the reflective region, the molding layer, and the auxiliary layer may be different.

Further, there may be provided a light emitting apparatus including: a first light emitting device for generating light; a second light emitting device for generating light; a reflector disposed between the first light emitting device and the second light emitting device to reflect light toward at least one of the first light emitting device and the second light emitting device; and a substrate for supporting the reflector, the first light emitting device, and the second light emitting device, wherein a length of a surface of the reflector is greater than a separation distance between the first light emitting device and the second light emitting device.

Further, there may be provided the light emitting apparatus in which the reflector is configured such that, when a predetermined value is obtained by dividing a horizontal length of a virtual extension line extending from a side surface of either the first light emitting device or the second light emitting device to a surface of the reflector by a height from a lower surface of the reflector to the virtual extension line, the horizontal length increases and the height decreases toward a center along the surface of the reflector so that the obtained value decreases.

Further, there may be provided the light emitting apparatus in which the reflector includes: a reflective region for reflecting light toward at least one of the first light emitting device and the second light emitting device; and a light absorbing region stacked on the reflective region to cover the reflective region and absorb light, and a width of the reflective region is greater than a separation distance between the first light emitting device and the second light emitting device.

Further, there may be provided the light emitting apparatus in which a width of the light absorbing region is equal to or smaller than the separation distance between the first light emitting device and the second light emitting device.

### Effects of Invention

According to embodiments of the present disclosure, because a reflector may reduce optical interference between a plurality of light emitting devices, a distinct contrast ratio and contrast may be achieved.

Furthermore, according to the embodiments of the present disclosure, because the reflector may reflect light toward the light emitting device, the light extraction efficiency may be increased.

Furthermore, according to the embodiments of the present disclosure, because light may be absorbed in a light-absorbing region, mixing of light between adjacent light emitting devices may be prevented, and color distinction between the light emitting devices may become clearer.

Furthermore, according to the embodiments of the present disclosure, because an auxiliary layer may diffuse or refract light, the light extraction efficiency may be improved.

### BRIEF DESCRIPTION OF DRAWINGS

FIG. 1 is a diagram illustrating a light emitting apparatus according to a first embodiment of the present disclosure.

FIG. 2 is an enlarged view of portion A of FIG. 1.

FIG. 3 is an enlarged view illustrating a first example of an upper surface and a lower surface of the light absorbing region of FIG. 1.

FIG. 4 is an enlarged view illustrating a second example of an upper surface and a lower surface of the light absorbing region of FIG. 1.

FIG. 5 is an enlarged view illustrating a third example of an upper surface and a lower surface of the light absorbing region of FIG. 1.

FIG. 6 is a diagram illustrating a light emitting apparatus according to a second embodiment of the present disclosure.

FIG. 7 is a diagram illustrating a light emitting apparatus according to a third embodiment of the present disclosure.

FIG. 8 is a diagram illustrating a light emitting apparatus according to a fourth embodiment of the present disclosure.

FIG. 9 is a diagram illustrating the light emitting apparatus of FIG. 8 when viewed from above.

### SPECIFIC CONTENTS FOR EMBODYING INVENTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z—axes, and may be interpreted in a broader sense. For example, the DR1-axis, the D2R-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus 1 (light emitting apparatus) according to a first embodiment will be described.

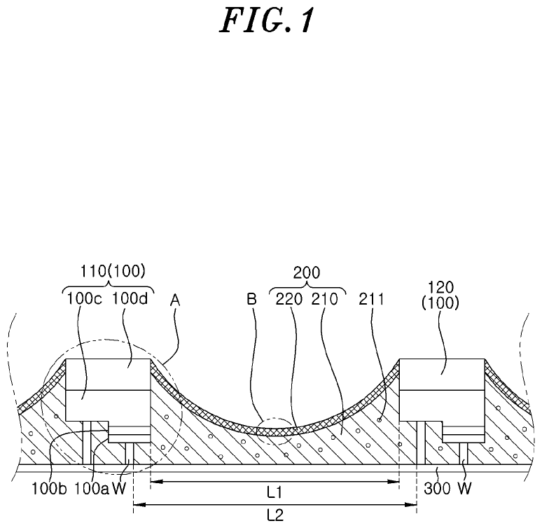

Referring to FIG. 1, the light emitting apparatus 1 according to the first embodiment may display characters, symbols, images, or video. Furthermore, the light emitting apparatus 1 may be mounted in a vehicle. This light emitting apparatus 1 may be included in a taillight, a headlight, a rear lamp, a tail lamp, an interior light, or the like. Furthermore, the light emitting apparatus 1 mounted in a vehicle may emit red-based light, yellow-based light, or white-based light to display information such as stop signals or characters to the outside. The light emitting apparatus 1 may be a high-quality display device that has a distinct contrast ratio and clear contrast by reducing optical interference between a plurality of light emitting devices 100 and minimizing interference between driving regions. The light emitting apparatus 1 may include a light emitting device 100, a reflector 200, and a substrate 300.

The light emitting device 100 may be supported by the substrate 300 to generate light. For example, the light emitting device 100 may generate any one of red light having a peak wavelength from 600 nm to 750 nm, green light having a peak wavelength from 490 nm to 570 nm, and blue light having a peak wavelength from 400 nm to 490 nm. The light emitting device 100 may include a first conductivity type semiconductor layer 100a, an active layer 100b, a second conductivity type semiconductor layer 100c, and a transmissive layer 100d.

The first conductivity type semiconductor layer 100a may include p-type impurities (e.g., Mg, Sr, Ba). In other words, the first conductivity type semiconductor layer 100a may be a p-type semiconductor layer. However, this is merely an example, and the first conductivity type semiconductor layer 100a may also include n-type impurities. Furthermore, the first conductivity type semiconductor layer 100a may be electrically connected to the substrate through a wire, an electrode W, or the like.

The active layer 100b may be disposed on the first conductivity type semiconductor layer 100a. In other words, the active layer 100b may be located between the first conductivity type semiconductor layer 100a and the second conductivity type semiconductor layer 100c. Furthermore, the first conductivity type semiconductor layer 100a and the active layer 100b may also form a mesa.

The second conductivity type semiconductor layer 100c may include n-type impurities (e.g., Si, Ge, Sn). This second conductivity type semiconductor layer 100c may be an n-type semiconductor layer. However, this is merely an example, and the second conductivity type semiconductor layer 100c may also include p-type impurities. Furthermore, the second conductivity type semiconductor layer 100c may be electrically connected to the substrate through a wire, an electrode W, or the like.

The transmissive layer 100d may be stacked on the second conductivity type semiconductor layer 100c. The transmissive layer 100d may be an insulating or conductive substrate, and may also be an insulating or conductive substrate joined by bonding. Furthermore, the transmissive layer 100d may be an insulating or conductive substrate for growing the first conductivity type semiconductor layer 100a, the active layer 100b, and the second conductivity type semiconductor layer 100c. For example, the transmissive layer 100d may include one or more of a silicon carbide substrate, a silicon substrate, a gallium nitride substrate, an aluminum nitride substrate, and a sapphire substrate.

Furthermore, unevenness may be formed on a side surface of the light emitting device 100. The unevenness may be formed on a peripheral surface of the light emitting device 100, but is not limited thereto. Furthermore, the side surface of the light emitting device 100 may be formed to be inclined. The width of this light emitting device 100 may become larger toward the top. Furthermore, a plurality of the light emitting devices 100 may be disposed on the substrate 300. The plurality of light emitting devices 100 may generate light of different peak wavelengths. The plurality of light emitting devices 100 may include a first light emitting device 110 and a second light emitting device 120.

The first light emitting device 110 may be supported by the substrate 300 so as to be spaced apart from the second light emitting device 120. The first light emitting device 110 may be surrounded by the reflector 200. A separation distance L1 between the first light emitting device 110 and the second light emitting device 120 may be smaller than a width L2 of a reflective region 210 of the reflector 200 to be described later. The reflection efficiency may be increased by securing a wider width L2 of the reflective region 210.

Furthermore, the separation distance L1 between the first light emitting device 110 and the second light emitting device 120 may be equal to or smaller than a width of a light absorbing region 220 to be described later. Furthermore, a horizontal separation distance L1 between the first light emitting device 110 and the second light emitting device 120 may be smaller than a surface length of the reflector 200. If the surface length of the reflector 200 is increased, the internal total reflectance that may occur at the surface of the reflector 200 may be increased, which may increase the probability of light being trapped inside the reflector 200.

The second light emitting device 120 may be supported by the substrate 300 to generate light of a similar peak wavelength as the first light emitting device 110. Alternatively, the second light emitting device 120 may be supported by the substrate 300 to generate light of a different peak wavelength from the first light emitting device 110. The second light emitting device 120 may be surrounded by the reflector 200.

The reflector 200 is supported by the substrate 300 so as to be disposed at the sides of the plurality of light emitting devices 100, and may reflect light emitted sideways from the plurality of light emitting devices 100 toward the plurality of light emitting devices 100. For example, the reflector 200 may be disposed between the plurality of light emitting devices 100. Furthermore, a plurality of reflectors 200 may be formed and disposed on the outside of the plurality of light emitting devices 100. In the reflector 200, the color of the reflector 200 when viewed from above may be different from the color of the reflector 200 when viewed from a side. The brightness of the reflector 200 when viewed from above may be lower than the brightness when viewed from a side. The color of the reflector 200 when viewed from above may be black. Light may be absorbed at an upper side of the reflector 200. Furthermore, the color of the reflector 200 when viewed from a side may be transparent or white. Light may be reflected from a side of the reflector 200. Therefore, the light extraction efficiency is increased inside the reflector 200, and because light may be absorbed at the upper side, the contrast may be increased.

The luminous intensity deviation of the light generated from the light emitting device 100 by the reflector 200 may be 0.015 or less. The luminous intensity deviation may be the luminous intensity deviation between light emitted upward among the light generated from the light emitting device 100 and light emitted in a direction deviated from the upward direction among the light generated from the light emitting device 100. For example, the angle between the light emitted upward and the light emitted in the direction deviated from the upward direction may be 50° to 80°.

The luminance change rate of the light generated from the light emitting device 100 by the reflector 200 may be 50% or less. The luminance change rate may be the luminance change rate between light emitted upward among the light from the light emitting device 100 and light emitted in the direction deviated from the upward direction among the light generated from the light emitting device 100. For example, the angle between the light emitted upward and the light emitted in the direction deviated from the upward direction may be 50° to 80°.

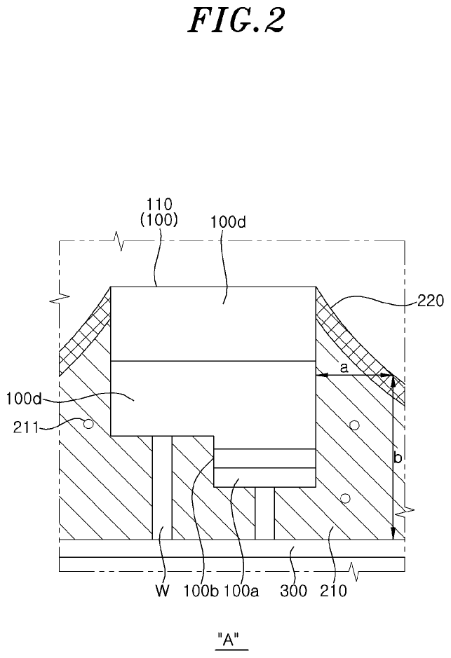

Referring further to FIG. 2, if a predefined value is calculated by dividing a predefined height b extending in a vertical direction by a predefined length a extending in a horizontal direction, in the reflector 200, the length a may be increased and the height b may be decreased toward a center along a surface of the reflector 200, so that the calculated value is decreased. The predefined length a is the length of a virtual extension line extending in the horizontal direction from a side surface of any one of the first light emitting device 110 and the second light emitting device 120 to the surface of the reflector 200. The predefined height b is the height from a lower surface of the reflector 200 to the extension line. The calculated value is the value obtained by dividing the height b by the length a. Furthermore, the length a of the extension line may be decreased and the height b may be increased toward the light emitting device 100 along the surface of the reflector 200.

Furthermore, the reflector 200 may include a reflective region 210 and a light absorbing region 220.

The reflective region 210 is disposed to be in contact with a side surface of at least one of the plurality of light emitting devices 100 and may reflect light toward the at least one of the plurality of light emitting devices 100. For example, the color of the reflective region 210 may be white. The reflectance of the reflective region 210 may be formed to be greater than the reflectance of the transmissive layer 100d. The light reflected from this reflective region 210 may pass through the light emitting device 100. The reflective region 210 may include an acrylic, silicone, or epoxy-based series, and a filler 211 for increasing reflectance. The filler 211 may include one or more of TiO₂ and SiO₂. Furthermore, the reflective region 210 may include carbon. The content of carbon in the reflective region 210 may be smaller than the content of carbon in the light absorbing region 220. Alternatively, the weight percentage (wt %) of carbon in the reflective region 210 may be smaller than the weight percentage (wt %) of carbon in the light absorbing region 220. Alternatively, the atomic percentage (at %) of carbon in the reflective region 210 may be smaller than the atomic percentage (at %) of carbon in the light absorbing region 220. Therefore, the difference in transmittance and reflectance between the light absorbing region 220 and the reflective region 210 may be large.

The reflective region 210 may be formed such that its thickness decreases toward the center. Furthermore, the thickness of the reflective region 210 may be formed to be greater than the thickness of the light absorbing region 220. In other words, the area of the side surface of the light emitting device 100 that the reflective region 210 contacts may be formed to be larger than the area of the side surface of the light emitting device 100 that the light absorbing region 220 contacts. The width of the reflective region 210 may be decreased as it is spaced further upward from the active layer 100b. Therefore, the loss of light emitted from the active layer 100b may be decreased. Furthermore, at least a portion of the reflective region 210 may be disposed below at least one of the first conductivity type semiconductor layer 100a and the second conductivity type semiconductor layer 100c. In other words, one side of the reflective region 210 may be disposed at a side of the electrode W electrically connected to the first conductivity type semiconductor layer 100a. The other side, opposite the one side of the reflective region 210, may be disposed at a side of the electrode W electrically connected to the second conductivity type semiconductor layer 100c. The width L2 of the reflective region 210 may be formed to be greater than the separation distance L1 between the second light emitting device 120 and the first light emitting device 110.

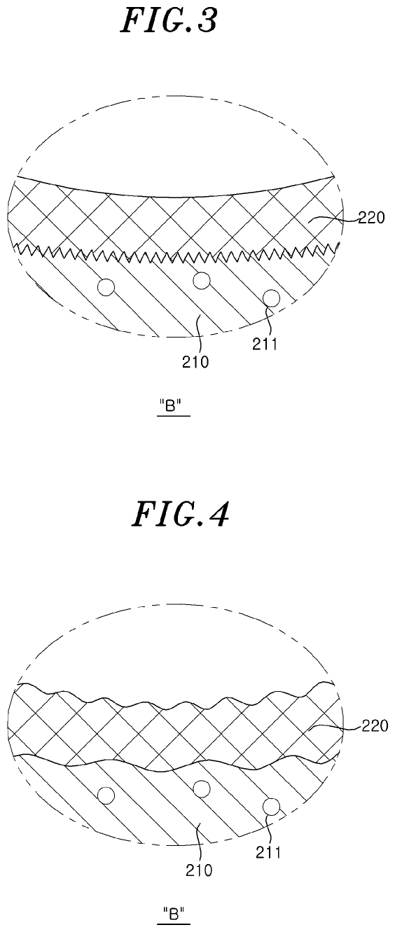

Referring further to FIGS. 3 to 5, the light absorbing region 220 may absorb light. The light absorbing region 220 is disposed on an upper side of the reflective region 210 and may cover the reflective region 210. The light absorbing region 220 may prevent the reflective region 210 from being exposed when viewed from above. The color of the light absorbing region 220 may be black. In one example, the light absorbing region 220 may be stacked on the reflective region 210. In other words, the light absorbing region 220 and the reflective region 210 may be separated into separate layers. Therefore, light may be refracted by the interface between the light absorbing region 220 and the reflective region 210, so that the light re-entering the reflective region 210 may be increased, and the emission of light to the outside of the reflective region 210 may be prevented. In another example, the light absorbing region 220 and the reflective region 210 may be integrally formed. Accordingly, the bonding strength between the light absorbing region 220 and the reflective region 210 may be increased.

The interface between the light absorbing region 220 and the reflective region 210 may be non-uniform. The roughness of an upper surface of the light absorbing region 220 and the roughness of a lower surface of the light absorbing region 220 may be different from each other.

As a first example, the upper surface of the light absorbing region 220 may be formed as a curved surface. Furthermore, roughness may be formed on the lower surface of the light absorbing region 220.

As a second example, the rate of change of roughness of the upper surface of the light absorbing region 220 may be greater than the rate of change of roughness of the lower surface of the light absorbing region 220. Here, the rate of change may be said to be large if the number of peaks and valleys of roughness is high based on the same horizontal area. Therefore, by increasing the surface area of the reflector 200, the reflector 200 may be made to appear darker when viewed from above.

As a third example, the lower surface of the light absorbing region 220 may be formed as a curved surface. Furthermore, roughness may be formed on the upper surface of the light absorbing region 220. Therefore, the absorbance may be controlled by making the thickness of the light absorbing region 220 non-uniform.

The width of the light absorbing region 220 may be equal to or smaller than the separation distance L1 between the first light emitting device 110 and the second light emitting device 120. The surface length of the light absorbing region 220 may be formed to be longer than the horizontal separation distance L1 between the first light emitting device 110 and the second light emitting device 120. Because the light absorbing area may be increased by the surface length of the light absorbing region 220, the relative sharpness of the light generated from the first light emitting device 110 and the second light emitting device 120 may be increased.

The substrate 300 may support the plurality of light emitting devices 100 and the reflector 200. The substrate 300 may also be electrically connected to the plurality of light emitting devices 100 through the electrode W. The substrate 300 may be formed of alumina, quartz, calcium zirconate, forsterite, SiC, graphite, fused silica, mullite, cordierite, zirconia, beryllia, aluminum nitride, LTCC (low temperature co-fired ceramic), paper phenolic, or an epoxy resin-based substrate. Further, the substrate 300 may include a wiring portion made of a metal or metal compound such as Cu, Al, Ag, Au, Ni, or W on an insulating layer formed of materials such as polyimide (PI), bismaleimide/triazine (BT), Teflon, PMMA, or polycarbonate (PC). The substrate 300 may be a printed circuit board (PCB) including metal wiring.

Hereinafter, the operation and effects of the light emitting apparatus 1 according to the first embodiment of the present disclosure will be described.

The light generated from the light emitting device 100 according to the first embodiment of the present disclosure may be emitted upward or sideways. The reflector 200 is disposed at a side of the light emitting device 100 and may reflect the light emitted sideways from the light emitting device 100 toward the light emitting device 100. The light reflected from the reflector 200 may pass through the light emitting device 100.

By the reflector 200, optical interference between the plurality of light emitting devices 100 may be reduced, so that a distinct contrast ratio and contrast may be formed.

Furthermore, because the reflector 200 may reflect light toward the light emitting device 100, the light extraction efficiency may be increased.

Furthermore, because light may be absorbed in the light absorbing region 220, mixing of light between adjacent light emitting devices 100 may be prevented, and the color distinction between the light emitting devices 100 may become clearer.

Furthermore, because the filler 211 may be included in the reflective region 210, the reflectance of the reflective region 210 may be increased.

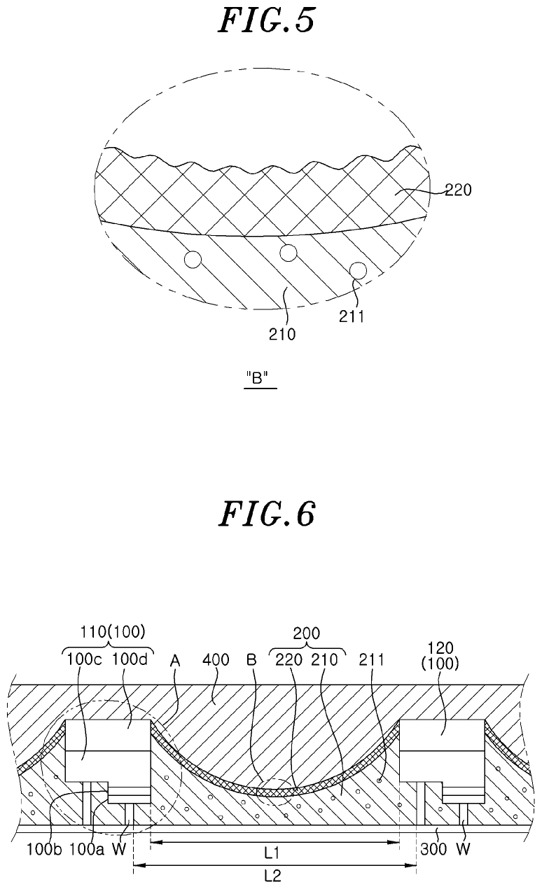

Hereinafter, a light emitting apparatus 1 according to a second embodiment of the present disclosure will be described with reference to FIG. 6. In describing the second embodiment, since there is a difference in that a molding layer 400 is further included, this difference will be mainly described.

The light emitting apparatus 1 may further include a molding layer 400. The molding layer 400 may be stacked on the reflector 200 and the plurality of light emitting devices 100. In other words, the molding layer 400 may cover the plurality of light emitting devices 100 and the light absorbing region 220. Light from the plurality of light emitting devices 100 may pass through the molding layer 400. The reflectance of the molding layer 400 may be formed to be lower than the reflectance of the reflective region 210. The refractive indices of the molding layer 400, the reflective region 210, and the transmissive layer 100d may be different. For example, the refractive index of the molding layer 400 may be 1.4 to 1.6, the refractive index of the reflective region 210 may be 1.3 to 1.5, and the refractive index of the transmissive layer 100d may be 1.6 to 1.8.

Hereinafter, the operation and effects of the light emitting apparatus 1 according to the second embodiment of the present disclosure will be described.

The light generated from the light emitting device 100 according to the second embodiment of the present disclosure may be emitted upward to pass through the molding layer 400, or may be emitted sideways. The reflector 200 is disposed at a side of the light emitting device 100 and may reflect the light emitted to the side of the light emitting device 100 toward the light emitting device 100. The light reflected from this reflector 200 may pass through the light emitting device 100 and the molding layer 400.

Because the molding layer 400 may cover the light emitting device 100, the molding layer 400 may protect the light emitting device 100.

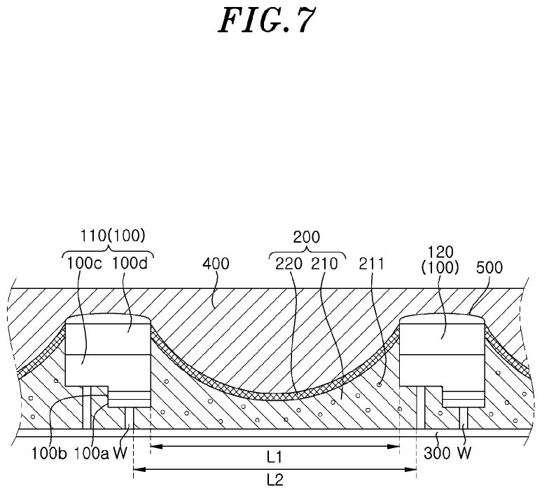

Hereinafter, a light emitting apparatus 1 according to a third embodiment of the present disclosure will be described with reference to FIG. 7. In describing the third embodiment, since there is a difference in that an auxiliary layer 500 is further included, this difference will be mainly described.

The auxiliary layer 500 is stacked on the light emitting device 100 and may diffuse or refract light. The auxiliary layer 500 may be covered by a molding layer. For example, the auxiliary layer 500 may be a lens or a film containing a diffusing agent. The shape of the auxiliary layer 500 when viewed from a side and the shape of the auxiliary layer 500 when viewed from above may be formed differently. The auxiliary layer 500 may have a semicircular shape when viewed from a side. Furthermore, the auxiliary layer 500 may have a rectangular shape when viewed from above.

The auxiliary layer 500 may be located between the light absorbing regions 220 of the plurality of reflectors 200. In other words, the auxiliary layer 500 may be surrounded by the light absorbing region 220 when viewed from above. The refractive index of this auxiliary layer 500 may be different from the refractive indices of the reflective region 210, the molding layer 400, and the transmissive layer 100d. For example, the refractive index of the auxiliary layer 500 may be 1.5 to 1.7.

The auxiliary layer 500 may be located within the region of the light emitting device 100. Therefore, light may be effectively collected.

Hereinafter, the operation and effects of the light emitting apparatus 1 according to the third embodiment of the present disclosure will be described.

The light generated from the light emitting device 100 according to the third embodiment of the present disclosure may sequentially pass through the auxiliary layer 500 and the molding layer 400. Furthermore, the light reflected from the reflector 200 may also sequentially pass through the light emitting device 100, the auxiliary layer 500, and the molding layer 400.

Since the auxiliary layer 500 can diffuse or refract light, the light extraction efficiency can be improved.

Hereinafter, a light emitting apparatus according to a fourth embodiment of the present disclosure will be described with reference to FIGS. 8 and 9. In describing the fourth embodiment, since there are differences in that an upper surface of the light absorbing region 220 may be disposed higher than an upper surface of the light emitting device 100 and that an opening 221 may be formed in the light absorbing region 220, these differences will be mainly described.

An upper surface of the reflective region 210 may be disposed at a similar or same position as an upper surface of the transmissive layer 100d. The reflective region 210 may be formed such that the upper surface of the light absorbing region 220 is disposed higher than the upper surface of the transmissive layer 100d.

An opening 221 for exposing the light emitting device 100 to the outside may be formed in the light absorbing region 220. An inner surface of the light absorbing region 220 may be disposed spaced apart from the light emitting device 100. Furthermore, the inner surface of the light absorbing region 220 may be disposed to surround an edge of the light emitting device 100 when viewed from above. The inner surface of the light absorbing region 220 may be circular when viewed from above. The opening 221 of the light absorbing region 220 may prevent an externally non-uniform appearance even if at least one of the plurality of light emitting devices 100 is rotated or tilted and thus non-uniformly disposed when the plurality of light emitting devices 100 are mounted.

Furthermore, the opening 221 of the light absorbing region 220 may expose a portion of the reflective region 210 to the outside. The opening 221 may allow light scattered, diffused, or reflected from the reflective region 210 to be emitted to the outside. If the plurality of light emitting devices 100 are formed with different positions or shapes, the external light emission shape (appearance) may be formed differently. Because the opening 221 may emit light from the reflective region 210, a uniform light emission shape may be provided even if the light emission shape of any one of the plurality of light emitting devices 100 is formed differently.

A portion of the molding layer 400 may pass through the opening 221 and be stacked on one or more of the reflective region 210, the light emitting device 100, and the auxiliary layer 500.

Hereinafter, the operation and effects of the light emitting apparatus 1 according to the fourth embodiment of the present disclosure will be described.

The opening 221 of the light absorbing region 220 may prevent an externally non-uniform appearance even if at least one of the plurality of light emitting devices 100 is rotated or tilted and thus non-uniformly disposed when the plurality of light emitting devices 100 are mounted.

Furthermore, since the opening 221 of the light absorbing region 220 can emit light from the reflective region 210, a uniform light emission shape may be provided even if the light emission shape of any one of the plurality of light emitting devices 100 is formed differently.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

### Description of Reference Numerals

1: light emitting apparatus 100: light emitting device
100a: first conductivity type semiconductor layer 100b: active layer
100c: second conductivity type semiconductor layer 100d: transmissive layer
110: first light emitting device 120: second light emitting device
200: reflector 210: reflecting region
211: filler 220: light absorbing region
221: opening 300: substrate
400: molding layer 500: auxiliary layer

1. A light emitting apparatus comprising:
a light emitting device for generating light;
a reflector disposed at a side of the light emitting device to reflect light toward the light emitting device; and
a substrate for supporting the light emitting device and the reflector,
wherein the reflector, when viewed from the side, has a region whose color differs from a color of the reflector when viewed from above.

2. The light emitting apparatus of claim 1, wherein the color of the reflector when viewed from above is black, and
the color of the reflector when viewed from the side is white.

3. The light emitting apparatus of claim 1, wherein a luminous intensity deviation of the light generated from the light emitting device is 0.015 or less, and
the luminous intensity deviation is a luminous intensity deviation between light emitted upward among the light generated from the light emitting device and light emitted in a direction deviated from the upward direction among the light generated from the light emitting device.

4. The light emitting apparatus of claim 1, wherein a luminance change rate of the light generated from the light emitting device is 50% or less, and
the luminance change rate is a luminance change rate between light emitted upward among the light generated from the light emitting device and light emitted in a direction deviated from the upward direction among the light generated from the light emitting device.

5. The light emitting apparatus of claim 1, wherein the reflector comprises:
a reflective region disposed at the side of the light emitting device to reflect light toward the light emitting device; and
a light absorbing region covering the reflective region and absorbing light.

6. The light emitting apparatus of claim 5, wherein a thickness of the reflective region is greater than a thickness of the light absorbing region.

7. The light emitting apparatus of claim 5, wherein the reflective region and the light absorbing region are integrally formed, and
an interface between the reflective region and the light absorbing region is non-uniform.

8. The light emitting apparatus of claim 5, wherein the light emitting device comprises:
a first conductivity type semiconductor layer;
an active layer stacked on the first conductivity type semiconductor layer; and
a second conductivity type semiconductor layer stacked on the active layer, and
wherein a width of the reflective region decreases as a distance upward from the active layer.

9. The light emitting apparatus of claim 8, wherein at least a portion of the reflective region is disposed below any one of the first conductivity type semiconductor layer and the second conductivity type semiconductor layer.

10. The light emitting apparatus of claim 5, wherein the reflective region and the light absorbing region include carbon, and
a content of the carbon in the light absorbing region is higher than a content of the carbon in the reflective region.

11. The light emitting apparatus of claim 5, wherein the reflective region and the light absorbing region are in contact with a side surface of the light emitting device, and
an area of the side surface of the light emitting device that the reflective region contacts is greater than an area of the side surface of the light emitting device that the light absorbing region contacts.

12. The light emitting apparatus of claim 5, further comprising a molding layer stacked on the light emitting device and the light absorbing region,
wherein a reflectance of the reflective region is greater than a reflectance of the molding layer.

13. The light emitting apparatus of claim 5, wherein the reflective region comprises a filler.

14. A light emitting apparatus comprising:
a light emitting device for generating light;
a substrate for supporting the light emitting device;
a reflector located at a side of the light emitting device to reflect light toward the light emitting device; and
an auxiliary layer stacked on the light emitting device and diffusing light,
wherein a color of the reflector when viewed from above and a color of the reflector when viewed from a side are different.

15. The light emitting apparatus of claim 14, wherein the reflector comprises:
a reflective region disposed at the side of the light emitting device to reflect light toward the light emitting device; and
a light absorbing region stacked on the reflective region to cover the reflective region and absorbing light.

16. The light emitting apparatus of claim 15, further comprising a molding layer covering the reflector and the auxiliary layer,
wherein refractive indices of the reflective region, the molding layer, and the auxiliary layer are different.

17. A light emitting apparatus comprising:
a first light emitting device for generating light;
a second light emitting device for generating light;
a reflector disposed between the first light emitting device and the second light emitting device to reflect light toward at least one of the first light emitting device and the second light emitting device; and
a substrate for supporting the reflector, the first light emitting device, and the second light emitting device,
wherein a length of a surface of the reflector is greater than a separation distance between the first light emitting device and the second light emitting device.

18. The light emitting apparatus of claim 17, wherein the reflector is configured such that, when a predetermined value is obtained by dividing a horizontal length of a virtual extension line extending from a side surface of either the first light emitting device or the second light emitting device to a surface of the reflector by a height from a lower surface of the reflector to the virtual extension line, the horizontal length increases and the height decreases toward a center along the surface of the reflector so that the obtained value decreases.

19. The light emitting apparatus of claim 17, wherein the reflector comprises:
a reflective region for reflecting light toward at least one of the first light emitting device and the second light emitting device; and
a light absorbing region stacked on the reflective region to cover the reflective region and absorb light, and
wherein a width of the reflective region is greater than a separation distance between the first light emitting device and the second light emitting device.

20. The light emitting apparatus of claim 19, wherein a width of the light absorbing region is equal to or smaller than the separation distance between the first light emitting device and the second light emitting device.
